(19) United States
(12) Patent Application Publication
(10) Pub. No.: US 2026/0260031 A1
(43) Pub. Date: Sep. 3, 2026

(54) METHOD FOR VERIFICATION AND VALIDATION OF NON-CONFORMANCE ANOMALIES IN A STRUCTURE

(71) Applicant: The Boeing Company, Arlington, VA (US)

(72) Inventors: Benjamin Pate, Renton, WA (US); Gregg Paporello, Wichita, KS (US); Tim Cundiff, Auburn, WA (US)

(21) Appl. No.: 19/532,050

(22) Filed: Feb. 6, 2026

Related U.S. Application Data
(60) Provisional application No. 63/765,175, filed on Feb. 28, 2025.

(51) Int. Cl. G06F 30/15

(52) U.S. Cl. CPC G06F 30/15

(57) ABSTRACT

An anomaly artifact and associated methods for generating and using the anomaly artifact to support inspection activities of an anomaly in a structure are disclosed. The anomaly artifact includes anomaly identification information, anomaly description information, anomaly inspection information, and anomaly location information consolidated into a single, structured reference usable during inspection activities of the anomaly. The anomaly location information may include map-based localization information mapped to a digital representation of the structure, which may be subdivided into zones such that the anomaly is represented by zone-specific anomaly artifacts.

### CROSS-REFERENCE TO RELATED APPLICATION

This application claims the benefit of U.S. Provisional Patent Application No. 63/765,175, filed Feb. 28, 2025, which is incorporated herein by reference in its entirety.

### FIELD

This disclosure relates generally to non-conformance anomaly documentation for structures, and more particularly to non-conformance anomaly artifacts and associated methods.

### BACKGROUND

Managing non-conformance (NC) anomalies in large or complex structures, such as aircraft, rockets, microchips, and other assemblies, can present significant challenges due to the volume, complexity, and distribution of anomalies. Conventional anomaly communication systems, such as Quality Management Systems (QMS), often store anomaly data in fragmented, disjointed, or cumbersome formats, lacking a consolidated format that organizes anomaly information in a manner suitable for efficient inspection preparation and execution. Anomaly data is often dispersed across multiple data sources (e.g., databases, spreadsheets, reports), thus requiring inspectors to manually compile and interpret data prior to conducting inspections. This fragmented approach increases the risk of oversight, prolongs inspection preparation time, and complicates anomaly resolution efforts. Additionally, inspections are frequently conducted at a whole-item level rather than a localized (e.g., zone-specific) level, making it difficult and costly to efficiently verify larger or complex anomalies in an organized manner.

### SUMMARY

The subject matter of the present application has been developed in response to the present state of the art, and particularly in response to the shortcomings associated with conventional anomaly communication and documentation approaches that have not yet been fully solved by currently available techniques. Accordingly, the subject matter of the present application has been developed to provide a non-conformation anomaly artifact and associated methods for generating and using the same, that overcome at least some of the above-mentioned shortcomings of prior art techniques.

The following is a non-exhaustive list of examples, which may or may not be claimed, of the subject matter, disclosed herein.

Disclosed herein is a method of generating an anomaly artifact for supporting inspection activities of an anomaly of a structure. The method includes aggregating anomaly data from one or more anomaly data sources to generate structured anomaly data for the anomaly, generating the anomaly artifact for the anomaly based on the structured anomaly data as a single reference usable during inspection activities of the anomaly, and storing and selectively updating the anomaly artifact in an anomaly management system to maintain a current and accurate representation of the anomaly. The anomaly artifact includes anomaly identification information, anomaly description information, anomaly inspection information, and anomaly location information. The preceding subject matter of this paragraph characterizes example 1 of the present disclosure.

Generating the anomaly artifact further includes populating the anomaly artifact according to a predefined artifact template having a standardized organization for the anomaly identification information, the anomaly description information, the anomaly inspection information, and the anomaly location information. The preceding subject matter of this paragraph characterizes example 2 of the present disclosure, wherein example 2 also includes the subject matter according to example 1, above.

The anomaly location information includes map-based localization information mapped to a digital representation of the structure to indicate a spatial location of the anomaly within the structure, the digital representation of the structure is subdivided into a plurality of zones, and the anomaly artifact is associated with at least one of the plurality of zones based on the anomaly location information. The preceding subject matter of this paragraph characterizes example 3 of the present disclosure, wherein example 3 also includes the subject matter according to example 1 or 2, above.

When the anomaly spans multiple zones of the plurality of zones, the method further includes generating a plurality of zone-specific anomaly artifacts of the anomaly, each zone-specific anomaly artifact corresponding to one of the multiple zones. The preceding subject matter of this paragraph characterizes example 4 of the present disclosure, wherein example 4 also includes the subject matter according to example 3, above.

Generating the anomaly artifact includes automatically generating the anomaly artifact based on the structured anomaly data. The preceding subject matter of this paragraph characterizes example 5 of the present disclosure, wherein example 5 also includes the subject matter according to any of examples 1-4, above.

Generating the anomaly artifact includes manually generating the anomaly artifact based on the structured anomaly data. The preceding subject matter of this paragraph characterizes example 6 of the present disclosure, wherein example 6 also includes the subject matter according to any of examples 1-4, above.

Generating the anomaly artifact further includes including at least one of at least one image associated with the anomaly, an anomaly severity level, an anomaly classification, or anomaly metadata associated with the anomaly artifact. The preceding subject matter of this paragraph characterizes example 7 of the present disclosure, wherein example 7 also includes the subject matter according to any of examples 1-6, above.

Selectively updating the anomaly artifact comprises at least one of updating the anomaly description information, updating the anomaly inspection information, or updating the anomaly location information. The preceding subject matter of this paragraph characterizes example 8 of the present disclosure, wherein example 8 also includes the subject matter according to any of examples 1-7, above.

The method further includes structuring the anomaly artifact for interoperability across a plurality of anomaly management systems, wherein the anomaly management system is one of the plurality of anomaly management systems, to support inspection related activities across different inspection contexts. The preceding subject matter of this paragraph characterizes example 9 of the present disclosure, wherein example 9 also includes the subject matter according to any of examples 1-8, above.

Further disclosed herein is a method of using an anomaly artifact for supporting inspection activities of an anomaly of a structure. The method includes aggregating anomaly data from one or more anomaly data sources to generate structured anomaly data for the anomaly, generating the anomaly artifact for the anomaly based on the structured anomaly data as a single reference usable during inspection activities of the anomaly, and storing and selectively updating the anomaly artifact in an anomaly management system to maintain a current and accurate representation of the anomaly. The method also includes mapping the anomaly location information of the anomaly artifact to a digital representation of the structure to provide spatial context for the anomaly and providing the anomaly artifact to at least one user to support inspection activities of the anomaly. The anomaly artifact includes anomaly identification information, anomaly description information, anomaly inspection information, and anomaly location information. The preceding subject matter of this paragraph characterizes example 10 of the present disclosure.

Mapping the anomaly location information includes including mapped localization information within the anomaly artifact. The preceding subject matter of this paragraph characterizes example 11 of the present disclosure, wherein example 11 also includes the subject matter according to example 10, above.

The digital representation of the structure is subdivided into a plurality of zones and mapping the anomaly location information further comprises associating the anomaly artifact with at least one of the plurality of zones. The preceding subject matter of this paragraph characterizes example 12 of the present disclosure, wherein example 12 also includes the subject matter according to any of examples 10 or 11, above.

When the anomaly spans multiple zones of the plurality of zones, the method further includes generating a plurality of zone-specific anomaly artifacts of the anomaly, each zone-specific anomaly artifact corresponding to one of the multiple zones. The preceding subject matter of this paragraph characterizes example 13 of the present disclosure, wherein example 13 also includes the subject matter according to example 12, above.

Providing the anomaly artifact to the at least one user includes presenting the anomaly location information in a manner that directs the at least one user to a specific zone of the plurality of zones of the digital representation corresponding to a region of the structure where the anomaly is located. The preceding subject matter of this paragraph characterizes example 14 of the present disclosure, wherein example 14 also includes the subject matter according to example 13, above.

Further disclosed herein is an anomaly artifact for supporting inspection activities of an anomaly of a structure. The anomaly artifact includes anomaly identification information comprising a unique anomaly identifier for the anomaly, anomaly description information describing the anomaly, anomaly inspection information defining one or more actions to be performed to inspect the anomaly, and anomaly location information indicating where the anomaly is located within the structure. The anomaly identification information, the anomaly description information, the anomaly inspection information, and the anomaly location information are consolidated into a single reference usable during inspection activities of the anomaly. The preceding subject matter of this paragraph characterizes example 15 of the present disclosure.

The anomaly artifact further includes at least one image associated with the anomaly, the at least one image depicting the anomaly or a region of the structure in which the anomaly is located. The preceding subject matter of this paragraph characterizes example 16 of the present disclosure, wherein example 16 also includes the subject matter according to example 15, above.

The anomaly artifact further includes metadata associated with the anomaly artifact, the metadata including at least one of a revision status, a creation timestamp, a modification timestamp, or a user identifier associated with a modification. The preceding subject matter of this paragraph characterizes example 17 of the present disclosure, wherein example 17 also includes the subject matter according to any of examples 15 or 16, above.

The anomaly location information includes map-based localization information mapped to a digital representation of the structure to indicate a spatial location of the anomaly within the structure. The preceding subject matter of this paragraph characterizes example 18 of the present disclosure, wherein example 18 also includes the subject matter according to any of examples 15-17, above.

The digital representation of the structure is subdivided into a plurality of zones and the anomaly location information associates the anomaly with at least one of the plurality of zones. The preceding subject matter of this paragraph characterizes example 19 of the present disclosure, wherein example 19 also includes the subject matter according to example 18, above.

When the anomaly spans multiple zones of the plurality of zones, the anomaly artifact is generated as one of a plurality of zone-specific anomaly artifacts, each zone-specific anomaly artifact corresponding to one of the multiple zones. The preceding subject matter of this paragraph characterizes example 20 of the present disclosure, wherein example 20 also includes the subject matter according to example 19, above.

The described features, structures, advantages, and/or characteristics of the subject matter of the present disclosure may be combined in any suitable manner in one or more examples and/or implementations. In the following description, numerous specific details are provided to impart a thorough understanding of examples of the subject matter of the present disclosure. One skilled in the relevant art will recognize that the subject matter of the present disclosure may be practiced without one or more of the specific features, details, components, materials, and/or methods of a particular example or implementation. In other instances, additional features and advantages may be recognized in certain examples and/or implementations that may not be present in all examples or implementations. Further, in some instances, well-known structures, materials, or operations are not shown or described in detail to avoid obscuring aspects of the subject matter of the present disclosure. The features and advantages of the subject matter of the present disclosure will become more fully apparent from the following description and appended claims, or may be learned by the practice of the subject matter as set forth hereinafter.

### BRIEF DESCRIPTION OF THE DRAWINGS

In order that the advantages of the subject matter may be more readily understood, a more particular description of the subject matter briefly described above will be rendered by reference to specific examples that are illustrated in the appended drawings. Understanding that these drawings, which are not necessarily drawn to scale, depict only certain examples of the subject matter and are not therefore to be considered to be limiting of its scope, the subject matter will be described and explained with additional specificity and detail through the use of the drawings, in which:

FIG. 1 is a schematic flow diagram of a method of generating an anomaly artifact for supporting inspection activities of an anomaly of a structure, according to one or more examples of the present disclosure;

FIG. 2 is a schematic flow diagram illustrating aggregation of anomaly data, generation of an anomaly artifact, and storage of the anomaly artifact, according to one or more examples of the present disclosure;

FIG. 3A is a schematic, block view illustrating an anomaly artifact, according to one or more examples of the present disclosure;

FIG. 3B is a schematic, representative view illustrating one example of an anomaly artifact populated with anomaly-related information, according to one or more examples of the present disclosure;

FIG. 4 is a schematic, representative view of a digital representation of a structure, illustrating map-based localization of an anomaly, according to one or more examples of the present disclosure;

FIG. 5A is a schematic, representative view of a digital representation of a structure, subdivided into a plurality of zones, illustrating association of an anomaly with a zone, according to one or more examples of the present disclosure;

FIG. 5B is a schematic, representative view of the digital representation of FIG. 5A, illustrating subdivision of an anomaly spanning multiple zones into a plurality of zone-specific anomaly artifacts, according to one or more examples of the present disclosure; and

FIG. 6 is a schematic flow diagram of a method of using an anomaly artifact for supporting inspection activities of an anomaly of a structure, according to one or more examples of the present disclosure.

### DETAILED DESCRIPTION

Reference throughout this specification to “one example,” “an example,” or similar language means that a particular feature, structure, or characteristic described in connection with the example is included in at least one example of the present disclosure. Appearances of the phrases “in one example,” “in an example,” and similar language throughout this specification may, but do not necessarily, all refer to the same example. Similarly, the use of the term “implementation” means an implementation having a particular feature, structure, or characteristic described in connection with one or more examples of the present disclosure, however, absent an express correlation to indicate otherwise, an implementation may be associated with one or more examples.

Disclosed herein are non-conformance anomaly artifacts and associated methods for generating and using the same. As used herein, non-conformance (NC) anomalies refer to deviations from predefined design, manufacturing, or operational specifications, including, but not limited to, defects, discrepancies, and other conditions affecting the performance, integrity, reliability, or appearance of the structure. NC anomalies, hereinafter referred to as “anomalies”, can arise from manufacturing inconsistencies, material degradation, assembly errors, environmental damage, operational stresses, fatigue, or other factors that cause a component or system to fall outside acceptable tolerances. Anomalies may vary in size and severity, ranging from minor surface imperfections to large-scale structural anomalies that require extensive corrective actions.

The disclosed anomaly artifact and methods provide an improved approach to organizing, contextualizing, and communicating anomaly-related information by treating the anomaly artifact itself as a primary inspection-support object. The anomaly artifact serves as a consolidated and structured reference that aggregates anomaly information from one or more data sources (e.g., a Quality Management System (QMS)) into a single, standalone artifact usable during inspection activities, such as verification of an anomaly. The anomaly artifact carries, in a standardized organization, anomaly identification information, anomaly description information, anomaly inspection information, and anomaly location information, thereby reducing reliance on users (e.g., inspectors) to manually reconcile information distributed across multiple systems or documents. In this manner, the anomaly artifact functions as a foundational reference for anomaly inspection activities and may be used consistently across different systems or operational contexts, including QMS and non-QMS environments, while maintaining traceability of anomaly-related information.

In some examples, the anomaly artifact is further enhanced through map-based localization, where the anomaly location information is mapped to a digital representation of the structure to provide spatial context. The digital representation may be subdivided into predefined zones, enabling localized representation of anomalies and, in some cases, subdivision of a single anomaly into multiple zone-specific anomaly artifacts.

The disclosed anomaly artifact and associated methods may be beneficial for large and/or complex structures and assemblies, such as aircraft, ships, industrial equipment, or large infrastructure components, where anomaly information is often geographically distributed and/or operationally complex. By providing a standardized, artifact-centric approach that consolidated anomaly information and, in some examples, couples it with spatial context, the disclosed subject matter may reduce inspection preparation effort, improve coordination across distributed teams and systems, and support more efficient, localized inspection activities.

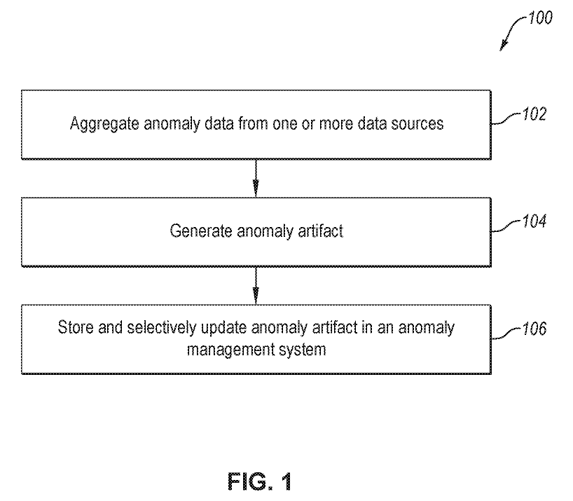

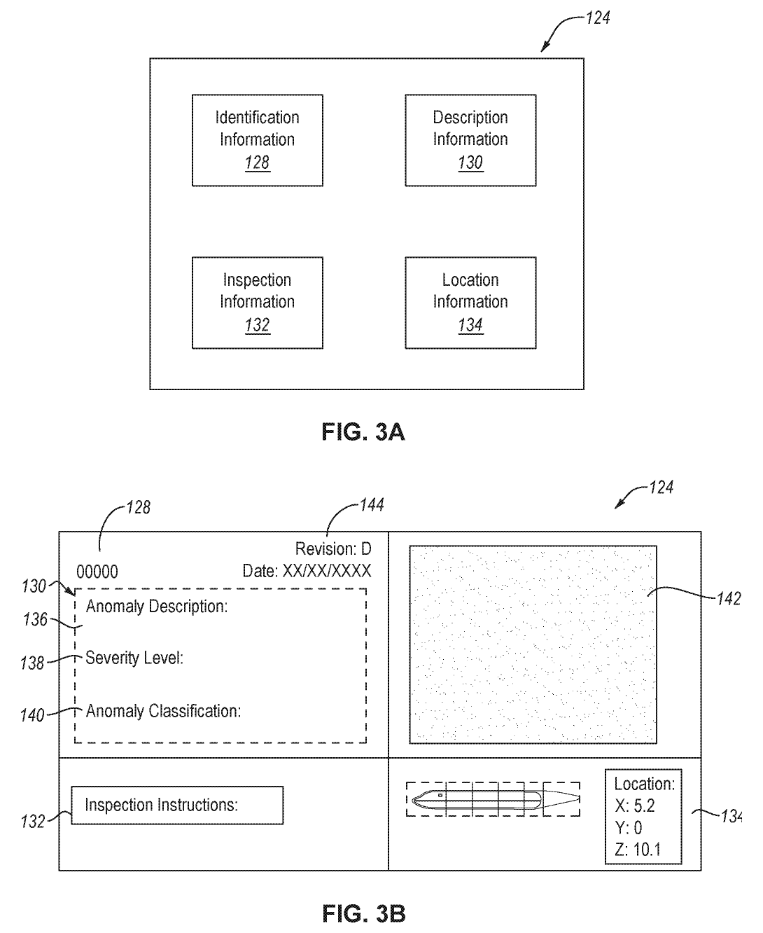

Referring to FIG. 1, according to one embodiment, a method 100 for generating an anomaly artifact for supporting inspection activities of an anomaly of a structure is shown. The method 100 is directed to collecting, organization, and consolidating anomaly-related information into a single reference usable during inspection activities. As used herein, “inspection activities” refers to one or more organization-defined activities performed in connection with an anomaly to evaluate, assess, document, and/or resolve the anomaly relative to a structure. Inspection activities may include, for example, confirming identification of the anomaly, confirming identification of the anomaly, confirming a location of the anomaly on the structure, inspecting the anomaly to determine whether a reported condition exists or does not exist, collecting observations or measurements, documenting inspection results, determining or recording a disposition of the anomaly (e.g., accept-as-is, rework, repair, replace, defer), performing or coordinating corrective actions associated with the anomaly, documenting complete of corrective actions, and confirming or validating that corrective actions having been completed and/or the anomaly has been resolved. The scope, sequence, and content of inspection activities may vary depending on organizational practices, regulatory or contractual requirements, inspection objectives, or application context. In some examples, inspection activities may be limited to determining whether an anomaly condition exists or does not exist at a specified location (e.g., existence verification). In other examples, inspection activities may include additional inspection, disposition, corrective action, and/or confirmation steps performed before, during, or after corrective action. Inspection activities are supported by, but are not limited to, the actions defined in the anomaly inspection information included within the anomaly artifact (see, e.g., FIG. 3A).

The anomaly artifact is intended to be used throughout an anomaly inspection lifecycle, including during verification and corrective action activities, until the anomaly is corrected or otherwise resolved. The disclosed method does not perform inspection or corrective actions but instead prepares and maintains anomaly-related information in a form that supports such activities.

The method 100 is applicable to a wide range of structures, including but not limited to aircraft, ships, industrial machinery, microchips, and large-scale infrastructure components. Such structures are often complex, geographically distributed, and composed of numerous interconnected parts or subsystems. In large and/or complex structures, anomaly-related information is frequently generated by multiple organizations, tools, or processes, resulting in information that is fragmented across systems and difficult to interpret in a unified manner. For example, anomaly-related information may be generated during manufacturing, assembly, inspection, maintenance, or repair activities and may originate from multiple organizations, systems, or processes operating across different locations of the structure. As a result, anomaly-related information is frequently fragmented across disparate systems and formats and can be difficult to interpret in a unified and spatially meaningful manner.

As illustrated in the figures herein, the method 100 is described using an aircraft as an example structure to demonstrate how anomaly information may be aggregated, organized, and contextualized for inspection preparation and use. However, the disclosed subject matter is not limited to aircraft, and the same techniques may be applied to other types of structures having similar complexity or inspection needs. The method 100 addresses these challenges by generating an artifact-centric representation of anomaly information that can be consistently used across inspection contexts without requiring inspectors or other users to manually reconcile information from disparate sources.

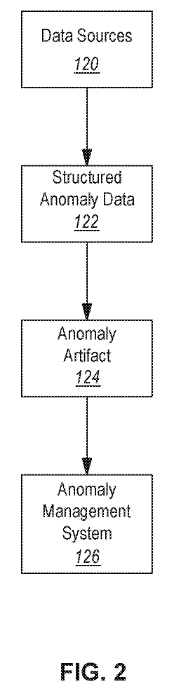

Referring generally to FIG. 1, and more specifically to FIG. 2, the method 100 includes, at block 102, aggregating anomaly data from one or more anomaly data sources 120. An anomaly data source 120 refers to any system, platform, or repository that stores anomaly-related information, including but not limited to Quality Management Systems (QMS), manufacturing execution systems, inspection records, maintenance databases, reports, and document-based tracking tools. In many cases, anomaly data within such sources is distributed across multiple records or formats and may lack a standardized organization suitable for direct inspection use. Additionally, in some cases, the anomaly data sources 120 may be associated with different organizations, facilities, or networks associated with manufacturing, inspection, maintenance, or repair of the structure.

Aggregation includes collecting, compiling, and organizing anomaly-related information from the one or more anomaly data sources 120 to generate structured anomaly data 122. The structured anomaly data 122 represents a normalized and standardized dataset derived from the aggregated anomaly data and may include, for example, anomaly identifiers, anomaly descriptions, severity indicators, images, location-related information, and inspection-related guidance. In some examples, aggregation may further include selecting or filtering anomaly-related information relevant to a particular anomaly to prepare the information for consolidation into a single anomaly artifact. By aggregating anomaly data into the structured anomaly data 122, the method 100 centralizes anomaly information and prepares it for use in generating a consolidated anomaly artifact, reducing the need for manual data reconciliation and improving consistency across inspection preparation activities. In some examples, the aggregation at block 102 is performed on an anomaly-by-anomaly basis, such that structured anomaly data 122 is generated for a particular anomaly and used to produce a corresponding anomaly artifact. In other examples, anomaly data from one or more anomaly data sources 120 is aggregated collectively and subsequently organized or partitioned to generate structured anomaly data 122 corresponding to individual anomalies.

The method 100 further includes, at block 104, generating an anomaly artifact 124 for an anomaly based on the structured anomaly data 122. The anomaly artifact 124 is generated as a structured, standalone reference that consolidates anomaly-related information into a single reference usable during inspection activities of the anomaly. The anomaly artifact 124 is derived from the structured anomaly data 122 and is formatted to organize anomaly information in a standardized and accessible manner suitable for inspection preparation and use, rather than as a raw data record. In other words, the anomaly artifact 124 consolidates anomaly-related information that may otherwise be distributed across multiple systems or records into a single reference associated with a particular anomaly, thereby reducing the need for inspectors or other users to manually reconcile anomaly information from disparate sources prior to or during inspection activities. In some examples, the anomaly artifact 124 and the structured anomaly data 122 may contain overlapping information; however, the anomaly artifact 124 presents the information in a form optimized for inspection preparation and communication.

In some examples, the anomaly artifact 124 is generated automatically based on the structured anomaly data 122. Automatic generation may be performed by an anomaly management system 126 using predefined rules, templates, or processing logic to populate the anomaly artifact 124 with relevant anomaly-related information. In other examples, the anomaly artifact 124 is generated manually, wherein personnel review the structured anomaly data 122 and input or organize anomaly-related information into the anomaly artifact 124. In yet other examples, automatic and manual generation may be combined, such that an automatically generated anomaly artifact 124 is reviewed, supplemented, or refined by personnel prior to use.

In some examples, the method includes creating or configuring an artifact template for a particular application or inspection context. The artifact template may be configured based on application-specific requirements, anomaly types, or user needs by selecting sections to include, adjusting a layout of sections, or adjusting prominence of sections within the template. After the artifact template is configured for the particular application or inspection context, the artifact template is treated as a predefined artifact template for generating anomaly artifacts, such that anomaly-related information from the structured anomaly data 122 is populated into the anomaly artifact 124 according to the standardized organization defined by the predefined artifact template.

In some examples, the predefined artifact template includes reserved fields, optional sections, or extensible regions that allow additional anomaly-related information to be included while maintaining the standardized organization. In one non-limiting example, the predefined artifact template employs a multi-region layout (e.g., a four-region or “four-square” arrangement) in which different regions are designated for different categories of anomaly-related information.

The method 100 further includes, at block 106, storing and selectively updating the anomaly artifact 124 in an anomaly management system 126 to maintain a current and accurate representation of the anomaly. That is, the anomaly artifact 124 is stored in an anomaly management system 126, which may comprise a digital platform, database, or repository configured to maintain anomaly artifacts and associated information. The anomaly management system 126 may support storage, retrieval, and selective updating of anomaly artifacts 124 such that each anomaly artifact reflects the latest available anomaly-related information as inspection activities progress. In this manner, the anomaly artifact 124 provides a current and accurate representation of the anomaly by incorporating updates resulting from inspection activities, changes to anomaly descriptions or locations, or completion of corrective actions, while avoiding reliance on outdated or superseded information. In some examples, the anomaly artifact 124 may be exported or stored in an offline format, such as a printed document or a locally managed digital file, for use in environments with limited network access or where physical documentation is required. In such examples, information recorded during inspection activities may be subsequently incorporated into a digital version of the anomaly artifact 124 when connectivity is available, such that the anomaly artifact 124 maintained in the anomaly management system 126 reflects a current and accurate representation of the anomaly.

In some examples, selectively updating the anomaly artifact 124 comprises updating one or more portions of the anomaly artifact, including updating the anomaly description information, updating the anomaly inspection information, or updating the anomaly location information, as additional information becomes available during inspection activities. In this manner, the anomaly artifact 124 is maintained as a single reference that is updated over time rather than replaced by multiple disconnected records.

Referring to FIGS. 3A and 3B, an anomaly artifact 124 is shown. FIG. 3A illustrates a conceptual representation of an anomaly artifact 124. FIG. 3B illustrates one non-limiting example of the anomaly artifact 124 having a defined format and populated with anomaly-related information. As described above, the anomaly artifact 124 is a structured, standalone reference generated for a particular anomaly and configured to consolidate anomaly-related information into a single reference usable during inspection activities. The anomaly artifact 124 is distinct from raw anomaly data records and is formatted to support inspection activities by presenting relevant information in an organized and accessible manner. The anomaly artifact 124 includes anomaly identification information 128, anomaly description information 130, anomaly inspection information 132, and anomaly location information 134. By consolidating these categories of information into a single artifact, the anomaly artifact 124 reduces reliance on multiple systems or documents and supports efficient inspection activities. In some examples, the anomaly artifact 124 is generated, maintained, and presented by one or more computing systems executing instructions configured to organize and present the anomaly-related information described herein.

In contrast to raw anomaly records, database entries, or reports generated by anomaly data sources, the anomaly artifact 124 is a purpose-built inspection reference configured to organize and present anomaly-related information in a manner that directly supports inspection activities. The anomaly artifact is not a mere storage container for anomaly data, but rather a structured representation designed to consolidate, contextualize, and communicate anomaly information as a unified reference during inspection. The anomaly artifact 124 is configured to be usable across different inspection contexts, including manufacturing, inspection, maintenance, and repair environments, without requiring users to reconstruct anomaly information from multiple systems. This portability enables consistent inspection practices across organizations, facilities, and operational stages. A separate anomaly artifact 124 is generated for each individual anomaly, such that anomaly-related information for each anomaly is maintained as a distinct and independently usable reference during inspection activities.

The anomaly identification information 128 uniquely identifies the anomaly and may include, for example, a distinct alphanumeric code, serial number, reference number, or other designation that allows for unambiguous identification of the anomaly. The anomaly identification information 128 enables association of all anomaly-related information within the anomaly artifact 124 and supports traceability of the anomaly across systems, records, and inspection activities, thereby reducing confusion and redundancy. In some examples, the anomaly identification information 128 is captured from an anomaly data source during aggregation of anomaly data and incorporated into the anomaly artifact 124. In other examples, the anomaly identification information 128 is automatically or manually assigned in the anomaly management system 126. In some examples, the anomaly identification information 128 is not intended to be modified after initial creation of the anomaly artifact 124 to avoid confusion with other anomalies.

The anomaly description information 130 includes information describing the anomaly and providing context to support recognition and understanding of the anomaly during inspection activities. For example, the anomaly description information 130 may include textual descriptions, classifications, severity indicators, or other descriptive information characterizing the nature of the anomaly or observed conditions associated with the anomaly. The anomaly description information 130 provides context to support understanding of the anomaly during inspection activities. As shown in FIG. 3B, the anomaly description information 130 may include, for example, textual description 136 describing the anomaly, a severity level 138 indicating a relative significance or priority of the anomaly, and an anomaly classification 140 identifying a type or category of the anomaly. These examples are provided for illustrative purposes only, and the anomaly description information 130 is not limited to the illustrated categories. In other examples, the anomaly description information 130 may include additional or alternative descriptive fields suitable for a particular application, structure, or inspection context.

The anomaly inspection information 132 define one or more actions to be performed during inspection activities of the anomaly. The anomaly inspection information 132 may specify inspection steps, observation requirements, measurements to be taken, equipment to be used, or response selections to complete inspection activities. For example, in some inspection contexts, inspection activities may involve confirming whether a reported condition exists or does not exist at the specified anomaly location (e.g., verification). In other inspection contexts, inspection activities may include confirming that one or more corrective actions have been performed and that the anomaly condition has been addressed in accordance with applicable requirements. Accordingly, the anomaly inspection information 132 may include actions for verifying completion, presence, absence, or effectiveness of corrective actions associated with the anomaly. By including the anomaly inspection information 132 within the anomaly artifact 124, users are provided with clear, actionable guidance tailored to the applicable inspection context without requiring reference to separate documentation.

The anomaly location information 134 indicates where the anomaly is located within the structure. The anomaly location information 134 may include textual location identifiers, component references, coordinate-based information, or map-based localization information mapped to a digital representation of the structure, as described in further detail below. The anomaly location information 134 may provide spatial context to assist users in locating the anomaly during inspection activities.

In some examples, the anomaly location information 134 included in the anomaly artifact 124 includes map-based localization information mapped to a digital representation of the structure. The map-based localization information indicates a spatial location of the anomaly within the structure and provides visual context to assist users in locating the anomaly during inspection activities. The digital representation may correspond to a model, diagram, or other representation of the structure that enables anomaly locations to be presented in relation to surrounding structural features. Further details regarding example mapping techniques and zone-based representations are described below with reference to subsequent figures.

In some examples, the anomaly artifact 124 further includes at least one image 142 associated with the anomaly, as shown in FIG. 3B. The at least one image 142 may depict the anomaly itself or a region of the structure in which the anomaly is located. For example, the image may include a photograph, annotated image, diagram, or other visual representation captured during manufacturing, inspection, maintenance, or inspection activities. Including one or more images within the anomaly artifact 124 provides visual context that assists users in recognizing the anomaly and understanding its physical characteristics during inspection, without requiring reference to separate image repositories or documentation. In some examples, the at least one image forms part or the entirety of the anomaly description information 130 by visually characterizing the anomaly or observed conditions. In other examples, the at least one image forms part of the anomaly location information 134 by visually indicating where the anomaly is located within the structure. In this manner, the anomaly artifact 124 may convey descriptive or location-related information visually, in addition to or in place of textual representations.

The anomaly artifact 124 may further includes metadata associated with the anomaly artifact. The metadata may include, for example, a revision status 144, a creation timestamp, a modification timestamp, or a user identifier associated with a modification to the anomaly artifact 124. Such metadata supports traceability of changes made to the anomaly artifact over time and assists users in determining the current state of the anomaly artifact during inspection activities. In particular, the revision status 144 indicates whether the anomaly artifact reflects an initial version, an updated version, or a superseded version of anomaly-related information. The revision status 144 may be updated as anomaly-related information changes, such as when additional inspection results are recorded, anomaly descriptions are refined, anomaly location information is clarified, or corrective action information is incorporated. By presenting the revision status 144 within the anomaly artifact 124, users can readily determine whether they are working with the most current version of the anomaly artifact during inspection, thereby reducing the risk of relying on outdated or incomplete anomaly information.

In some examples, the anomaly artifact 124 is structured for interoperability across a plurality of anomaly management systems. Rather than being confined to a single system or platform, the anomaly artifact 124 is formatted as a self-contained and standardized reference that can be exchanged, accessed, or utilized across different anomaly management systems and inspection contexts. This interoperability allows anomaly artifacts to be generated in one system and used in other systems associated with manufacturing, inspection, maintenance, repair, or supplier operations, while preserving the organization and content of the anomaly-related information. By structuring the anomaly artifact 124 for interoperability, inspection activities may be supported across different organizations, facilities, or network environments without requiring users to manually reconcile anomaly information from disparate systems.

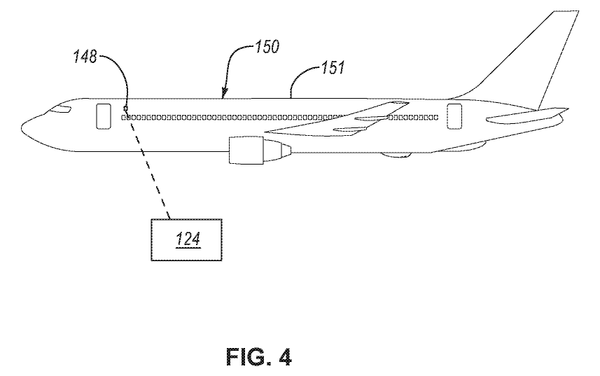

In some examples, the anomaly location information 134 included in the anomaly artifact 124 includes map-based localization information mapped to a digital representation of the structure. Referring to FIG. 4, an example digital representation 150 of a structure is shown. As used herein, a digital representation 150 of the structure refers to a map-based or spatial representation that depicts the structure and supports localization of anomalies relative to physical features of the structure. In the illustrated example, the digital representation 150 depicts an aircraft 151. The aircraft 151 includes an anomaly 148 associated with the structure that is indicated at a particular location on the digital representation 150, and an anomaly artifact 124 is associated with the anomaly 148. The digital representation 150 may be generated from computer-aided design (CAD) models, engineering datasets, inspection records, or other data sources that describe the structure. Mapping the anomaly location information to the digital representation 150 provides spatial context for the anomaly 148, enabling users to understand where the anomaly is located relative to the overall structure and surrounding structural features during inspection activities. The digital representation may include two-dimensional or three-dimensional visual maps, sectional views, surface maps, or other spatial representations suitable for locating anomalies within the structure.

In some examples, the digital representation 150, or a relevant portion thereof, is included within the anomaly artifact 124 as part of the anomaly location information. In other examples, the anomaly artifact 124 includes location information derived from the map-based localization and encoded in a structured form, such as textual descriptors, tabular entries, or charted location data, that conveys the spatial position of the anomaly relative to the structure without embedding the full digital representation.

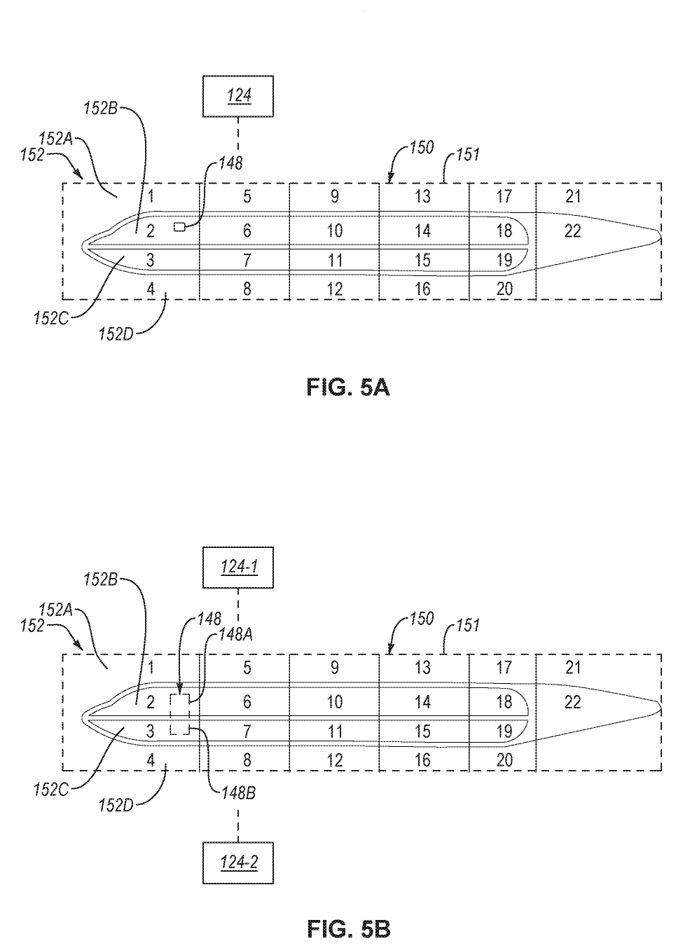

In some examples, the digital representation 150 of the structure is maintained as a single, undivided representation, as shown in FIG. 4. In other examples, as shown in FIGS. 5A and 5B, the digital representation 150 of the structure is subdivided into a plurality of zones 152, where each zone represents a defined portion of the structure for purposes of anomaly localization and inspection. The plurality of zones 152 may be defined based on structural features, manufacturing or assembly regions, inspection access considerations, or other application-specific criteria. In some examples, the digital representation 150 includes hierarchical divisions, such as zones and sub-zones, to support more granular organization of anomaly location information. The anomaly artifact 124 is associated with at least one of the plurality of zones 152 based on the anomaly location information within the digital representation 150.

Subdividing the digital representation 150 into zones enables anomaly localization to be expressed relative to specific portions of the structure rather than solely at a whole-structure level. This zonal organization supports more targeted inspection activities by allowing users to focus on relevant areas of the structure associated with a particular anomaly. In large or complex structures, such as aircraft, zonal association of anomaly artifacts can improve clarity, reduce ambiguity in anomaly location, and facilitate coordination among users responsible for inspection activities in different regions of the structure.

As shown in FIG. 5A, the plurality of zones 152 of the digital representation 150 includes a first zone 152A, a second zone 152B, a third zone 152C, a fourth zone 152D, and additional zones that are unlabeled for clarity. In this example, the anomaly location information indicates that an anomaly 148 is located within the second zone 152B, such that the corresponding anomaly artifact 124 is associated with the second zone 152B. In other examples, an anomaly may span multiple zones of the digital representation 150. In such cases, when an anomaly spans multiple zones, the anomaly is subdivided into a plurality of zone-specific anomaly artifacts.

When an anomaly spans multiple zones within the digital representation 150, the anomaly artifact 124 is generated as one of a plurality of zone-specific anomaly artifacts. That is, each zone-specific anomaly artifact corresponds to a respective zone and includes anomaly-related information associated with the portion of the anomaly located within that zone. For example, as shown in FIG. 5B, an anomaly spanning the second zone 152B and the third zone 152C is split into two anomalies, a first anomaly 148A and a second anomaly 148B, and is further represented by multiple zone-specific anomaly artifacts 124-1 and 124-2, respectively. Each zone-specific anomaly artifact supports localized inspection activities within its corresponding zone, while remaining associated with the same underlying anomaly.

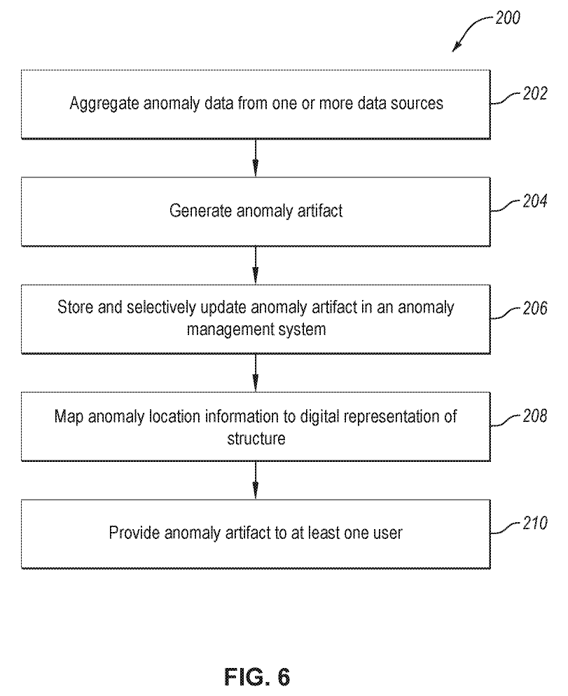

Referring to FIG. 6, a method 200 for supporting inspection activities of an anomaly of a structure is shown. The method 200 includes, at block 202, aggregating anomaly data from one or more anomaly data sources 120 to generate structured anomaly data 122 for the anomaly. This aggregation step may be performed in the same manner as described above with respect to block 102 of method 100. In some examples, the aggregation is performed specifically to support preparation of an anomaly artifact for use in inspection activities. At block 204, method 200 includes generating an anomaly artifact 124 for the anomaly based on the structured anomaly data. The anomaly artifact 124 is generated as a single reference usable during inspection activities and includes anomaly identification information 128, anomaly description information 130, anomaly inspection information 132, and anomaly location information 134, as described above. Generation of the anomaly artifact 124 enables anomaly-related information to be presented in a form suitable for use by one or more users during inspection activities.

The method 200 also includes, at block 206, storing and selectively updating the anomaly artifact in an anomaly management system 126 to maintain a current and accurate representation of the anomaly. As inspection activities progress, information associated with the anomaly artifact may be selectively updated, such as updates to anomaly description information 130, the anomaly inspection information 132, or the anomaly location information 134. This allows the anomaly artifact 124 to reflect the latest available information without altering the anomaly identification information.

At block 208, method 200 includes mapping the anomaly location information 134 of the anomaly artifact 124 to a digital representation 150 of the structure to provide spatial context for the anomaly. The mapping associates the anomaly with a location on the digital representation 150, enabling users to understand where the anomaly is located relative to physical features of the structure. In some examples, the mapped localization information derived from the digital representation 150 is included directly within the anomaly artifact 124, such that the anomaly artifact presents spatial location information without requiring the user to separately access the digital representation. In other examples, the anomaly artifact 124 includes a reference, link, or identifier that associates the anomaly artifact with the mapped location in the digital representation 150, while still providing sufficient anomaly location information within the anomaly artifact to support inspection activities.

In some examples, the digital representation 150 is subdivided into a plurality of zones 152, and the anomaly artifact 124 is associated with at least one of the zones based on the mapped anomaly location information, as described above.

At block 210, method 200 includes providing the anomaly artifact 124 to at least one user to support inspection activities of the anomaly. Providing the anomaly artifact 124 may include presenting the anomaly artifact 124 via a user interface, exporting the anomaly artifact 124 to a portable format, or otherwise making the anomaly artifact 124 accessible to the user. By providing the anomaly artifact 124 as a single, consolidated reference, method 200 enables users to perform inspection activities using anomaly-related information without relying on multiple separate systems or documents. The anomaly artifact 124 serves as the primary reference used by personnel throughout inspection activities, such that the information required to identify, locate, inspect, assess, and support corrective action of the anomaly is obtained directly from the anomaly artifact without requiring access to multiple underlying systems or records. In some examples, the anomaly artifact 124 is used to support inspection activities from initial identification of the anomaly through corrective action and resolution of the anomaly.

In some examples, the methods and techniques described herein are implemented, in whole or in part, by one or more computing devices. Such computing devices may include one or more processors, memory devices, storage devices, and communication interfaces, and may execute software instructions, firmware, or logic configured to perform the described operations. In some examples, the functions associated with aggregating anomaly data, generating anomaly artifacts, mapping anomaly locations, storing and updating anomaly artifacts, and presenting anomaly artifacts to users are performed by one or more software modules or logical components executing on the one or more computing devices. The described operations may be performed automatically, semi-automatically, or in combination with user input, depending on the implementation and inspection context.

In summary, the disclosed anomaly artifact and associated methods provide an artifact-centric approach to anomaly inspection activities in which anomaly-related information is consolidated into a single, structured reference usable throughout the inspection lifecycle. By integrating anomaly identification information, descriptive information, inspection information, and location information, including map-based localization tied to a digital representation of the structure, the anomaly artifact serves as the primary reference for personnel performing inspection activities. The disclosed techniques further support subdivision of anomalies into zone-specific anomaly artifacts for targeted inspection within defined regions of a structure, while maintaining traceability, revision control, and interoperability across systems. This approach reduces reliance on disparate records and systems, improves efficiency and consistency of inspection activities, and is particularly well suited for large or complex structures where accurate localization and coordinated inspection are critical.

In the above description, certain terms may be used such as "up," "down," "upper," "lower," "horizontal," "vertical," "left," "right," “over,” “under” and the like. These terms are used, where applicable, to provide some clarity of description when dealing with relative relationships. But, these terms are not intended to imply absolute relationships, positions, and/or orientations. For example, with respect to an object, an "upper" surface can become a "lower" surface simply by turning the object over. Nevertheless, it is still the same object. Further, the terms “including,” “comprising,” “having,” and variations thereof mean “including but not limited to” unless expressly specified otherwise. An enumerated listing of items does not imply that any or all of the items are mutually exclusive and/or mutually inclusive, unless expressly specified otherwise. The terms “a,” “an,” and “the” also refer to “one or more” unless expressly specified otherwise. Further, the term “plurality” can be defined as “at least two.” Moreover, unless otherwise noted, as defined herein a plurality of particular features does not necessarily mean every particular feature of an entire set or class of the particular features.

The term “about” or “substantially” in some embodiments, is defined to mean within +/-5% of a given value, however in additional embodiments any disclosure of “about” may be further narrowed and claimed to mean within +/- 4% of a given value, within +/- 3% of a given value, within +/- 2% of a given value, within +/- 1% of a given value, or the exact given value. Further, when at least two values of a variable are disclosed, such disclosure is specifically intended to include the range between the two values regardless of whether they are disclosed with respect to separate embodiments or examples, and specifically intended to include the range of at least the smaller of the two values and/or no more than the larger of the two values. Additionally, when at least three values of a variable are disclosed, such disclosure is specifically intended to include the range between any two of the values regardless of whether they are disclosed with respect to separate embodiments or examples, and specifically intended to include the range of at least the A value and/or no more than the B value, where A may be any of the disclosed values other than the largest disclosed value, and B may be any of the disclosed values other than the smallest disclosed value.

Additionally, instances in this specification where one element is “coupled” to another element can include direct and indirect coupling. Direct coupling can be defined as one element coupled to and in some contact with another element. Indirect coupling can be defined as coupling between two elements not in direct contact with each other, but having one or more additional elements between the coupled elements. Further, as used herein, securing one element to another element can include direct securing and indirect securing. Additionally, as used herein, “adjacent” does not necessarily denote contact. For example, one element can be adjacent another element without being in contact with that element.

As used herein, the phrase “at least one of”, when used with a list of items, means different combinations of one or more of the listed items may be used and only one of the items in the list may be needed. The item may be a particular object, thing, or category. In other words, “at least one of” means any combination of items or number of items may be used from the list, but not all of the items in the list may be required. For example, “at least one of item A, item B, and item C” may mean item A; item A and item B; item B; item A, item B, and item C; or item B and item C. In some cases, “at least one of item A, item B, and item C” may mean, for example, without limitation, two of item A, one of item B, and ten of item C; four of item B and seven of item C; or some other suitable combination.

Unless otherwise indicated, the terms "first," "second," etc. are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item.

As used herein, a system, apparatus, structure, article, element, component, or hardware “configured to” perform a specified function is indeed capable of performing the specified function without any alteration, rather than merely having potential to perform the specified function after further modification. In other words, the system, apparatus, structure, article, element, component, or hardware “configured to” perform a specified function is specifically selected, created, implemented, utilized, programmed, and/or designed for the purpose of performing the specified function. As used herein, “configured to” denotes existing characteristics of a system, apparatus, structure, article, element, component, or hardware which enable the system, apparatus, structure, article, element, component, or hardware to perform the specified function without further modification. For purposes of this disclosure, a system, apparatus, structure, article, element, component, or hardware described as being “configured to” perform a particular function may additionally or alternatively be described as being “adapted to” and/or as being “operative to” perform that function.

The schematic flow chart diagrams included herein are generally set forth as logical flow chart diagrams. As such, the depicted order and labeled steps are indicative of one example of the presented method. Other steps and methods may be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow chart diagrams, they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a particular method occurs may or may not strictly adhere to the order of the corresponding steps shown.

Many of the functional units described in this specification have been labeled as modules, to more particularly emphasize their implementation independence. For example, a module may be implemented as a hardware circuit comprising custom very large scale integrated (“VLSI”) circuits or gate arrays, off-the-shelf semiconductors such as logic chips, transistors, or other discrete components. A module may also be implemented in programmable hardware devices such as a field programmable gate array (“FPGA”), programmable array logic, programmable logic devices or the like.

Modules may also be implemented in software for execution by various types of processors. An identified module of program code may, for instance, comprise one or more physical or logical blocks of computer instructions which may, for instance, be organized as an object, procedure, or function. Nevertheless, the executables of an identified module need not be physically located together but may comprise disparate instructions stored in different locations which, when joined logically together, comprise the module and achieve the stated purpose for the module.

Indeed, a module of program code may be a single instruction, or many instructions, and may even be distributed over several different code segments, among different programs, and across several memory devices. Similarly, operational data may be identified and illustrated herein within modules and may be embodied in any suitable form and organized within any suitable type of data structure. The operational data may be collected as a single data set or may be distributed over different locations including over different storage devices, and may exist, at least partially, merely as electronic signals on a system or network. Where a module or portions of a module are implemented in software, the program code may be stored and/or propagated on in one or more computer readable medium(s).

The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (“RAM”), a read-only memory (“ROM”), an erasable programmable read-only memory (“EPROM” or Flash memory), a static random access memory (“SRAM”), a portable compact disc read-only memory (“CD-ROM”), a digital versatile disk (“DVD”), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (“ISA”) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the "C" programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (“LAN”) or a wide area network (“WAN”), or the connection may be made to an external computer (for example, through the Internet using an Internet Service Provider). In some embodiments, electronic circuitry including, for example, programmable logic circuitry, field-programmable gate arrays (“FPGA”), or programmable logic arrays (“PLA”) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The schematic flowchart diagrams and/or schematic block diagrams in the Figures illustrate the architecture, functionality, and operation of possible implementations of apparatuses, systems, methods and computer program products according to various embodiments of the present invention. In this regard, each block in the schematic flowchart diagrams and/or schematic block diagrams may represent a module, segment, or portion of code, which comprises one or more executable instructions of the program code for implementing the specified logical function(s).

Although various arrow types and line types may be employed in the flowchart and/or block diagrams, they are understood not to limit the scope of the corresponding embodiments. Indeed, some arrows or other connectors may be used to indicate only the logical flow of the depicted embodiment. For instance, an arrow may indicate a waiting or monitoring period of unspecified duration between enumerated steps of the depicted embodiment. It will also be noted that each block of the block diagrams and/or flowchart diagrams, and combinations of blocks in the block diagrams and/or flowchart diagrams, can be implemented by special purpose hardware-based systems that perform the specified functions or acts, or combinations of special purpose hardware and program code.

The present subject matter may be embodied in other specific forms without departing from its spirit or essential characteristics. The described examples are to be considered in all respects only as illustrative and not restrictive. All changes which come within the meaning and range of equivalency of the claims are to be embraced within their scope.

What is claimed is:

1. A method of generating an anomaly artifact for supporting inspection activities of an anomaly of a structure, the method comprising:
aggregating anomaly data from one or more anomaly data sources to generate structured anomaly data for the anomaly;
generating the anomaly artifact for the anomaly based on the structured anomaly data as a single reference usable during inspection activities of the anomaly, wherein the anomaly artifact comprises anomaly identification information, anomaly description information, anomaly inspection information, and anomaly location information; and
storing and selectively updating the anomaly artifact in an anomaly management system to maintain a current and accurate representation of the anomaly.

2. The method of claim 1, wherein generating the anomaly artifact further comprises populating the anomaly artifact according to a predefined artifact template having a standardized organization for the anomaly identification information, the anomaly description information, the anomaly inspection information, and the anomaly location information.

3. The method of claim 1, wherein:
the anomaly location information comprises map-based localization information mapped to a digital representation of the structure to indicate a spatial location of the anomaly within the structure;
the digital representation of the structure is subdivided into a plurality of zones; and
the anomaly artifact is associated with at least one of the plurality of zones based on the anomaly location information.

4. The method of claim 3, wherein, when the anomaly spans multiple zones of the plurality of zones, the method further comprises generating a plurality of zone-specific anomaly artifacts of the anomaly, each zone-specific anomaly artifact corresponding to one of the multiple zones.

5. The method of claim 1, wherein generating the anomaly artifact comprises automatically generating the anomaly artifact based on the structured anomaly data.

6. The method of claim 1, wherein generating the anomaly artifact comprises manually generating the anomaly artifact based on the structured anomaly data.

7. The method of claim 1, wherein generating the anomaly artifact further comprises including at least one of:
at least one image associated with the anomaly;
an anomaly severity level;
an anomaly classification; or
anomaly metadata associated with the anomaly artifact.

8. The method of claim 1, wherein selectively updating the anomaly artifact comprises at least one of:
updating the anomaly description information;
updating the anomaly inspection information; and
updating the anomaly location information.

9. The method of claim 1, further comprising structuring the anomaly artifact for interoperability across a plurality of anomaly management systems, wherein the anomaly management system is one of the plurality of anomaly management systems, to support inspection related activities across different inspection contexts.

10. A method of using an anomaly artifact for supporting inspection activities of an anomaly of a structure, the method comprising:
aggregating anomaly data from one or more anomaly data sources to generate structured anomaly data for the anomaly;
generating the anomaly artifact for the anomaly based on the structured anomaly data as a single reference usable during inspection activities of the anomaly, wherein the anomaly artifact comprises anomaly identification information, anomaly description information, anomaly inspection information, and anomaly location information;
storing and selectively updating the anomaly artifact in an anomaly management system to maintain a current and accurate representation of the anomaly;
mapping the anomaly location information of the anomaly artifact to a digital representation of the structure to provide spatial context for the anomaly; and
providing the anomaly artifact to at least one user to support inspection activities of the anomaly.

11. The method of claim 10, wherein mapping the anomaly location information comprises including mapped localization information within the anomaly artifact.

12. The method of claim 10, wherein:
the digital representation of the structure is subdivided into a plurality of zones; and
mapping the anomaly location information further comprises associating the anomaly artifact with at least one of the plurality of zones.

13. The method of claim 12, wherein, when the anomaly spans multiple zones of the plurality of zones, the method further comprises generating a plurality of zone-specific anomaly artifacts of the anomaly, each zone-specific anomaly artifact corresponding to one of the multiple zones.

14. The method of claim 13, wherein providing the anomaly artifact to the at least one user comprises presenting the anomaly location information in a manner that directs that at least one user to a specific zone of the plurality of zones of the digital representation corresponding to a region of the structure where the anomaly is located.

15. An anomaly artifact for supporting inspection activities of an anomaly of a structure, the anomaly artifact comprising:
anomaly identification information comprising a unique anomaly identifier for the anomaly;
anomaly description information describing the anomaly;
anomaly inspection information defining one or more actions to be performed to inspect the anomaly; and
anomaly location information indicating where the anomaly is located within the structure;
wherein the anomaly identification information, the anomaly description information, the anomaly inspection information, and the anomaly location information are consolidated into a single reference usable during inspection activities of the anomaly.

16. The anomaly artifact of claim 15, further comprising at least one image associated with the anomaly, the at least one image depicting the anomaly or a region of the structure in which the anomaly is located.

17. The anomaly artifact of claim 15, further comprising metadata associated with the anomaly artifact, the metadata including at least one of a revision status, a creation timestamp, a modification timestamp, or a user identifier associated with a modification.

18. The anomaly artifact of claim 15, wherein the anomaly location information comprises map-based localization information mapped to a digital representation of the structure to indicate a spatial location of the anomaly within the structure.

19. The anomaly artifact of claim 18, wherein:
the digital representation of the structure is subdivided into a plurality of zones; and
the anomaly location information associates the anomaly with at least one of the plurality of zones.

20. The anomaly artifact of claim 19, wherein, when the anomaly spans multiple zones of the plurality of zones, the anomaly artifact is generated as one of a plurality of zone-specific anomaly artifacts, each zone-specific anomaly artifact corresponding to one of the multiple zones.
